(19) United States
(12) Patent Application Publication
(10) Pub. No.: US 2026/0314400 A1
(43) Pub. Date: Oct. 8, 2026

(54) THERMALLY CONDUCTIVE SHEET, HEAT DISSIPATION DEVICE, AND METHOD FOR PRODUCING THERMALLY CONDUCTIVE SHEET

(71) Applicant: RESONAC CORPORATION, Minato-ku, Tokyo (JP)

(72) Inventors: Mika KOBUNE, Minato-ku, Tokyo (JP); Ricardo Mizoguchi GORGOLL, Minato-ku, Tokyo (JP)

(21) Appl. No.: 19/480,032

(22) PCT Filed: Oct. 26, 2023
(86) PCT No.: PCT/JP2023/038774

§ 371 Date: Oct. 30, 2025

(51) Int. Cl. H10W 40/20

(52) U.S. Cl. CPC H10W 40/233

(57) ABSTRACT

A thermal conductive sheet including: a thermal conductive layer containing at least one graphite particle (A) selected from the group consisting of a scale-like particle, an ellipsoidal particle, and a rod-like particle, in which in a case of the scale-like particle, a plane direction thereof is oriented in a thickness direction, in a case of the ellipsoidal particle, a longitudinal direction thereof is oriented in a thickness direction is oriented in a thickness direction, and in a case of the rod-like particle, a longitudinal direction thereof is oriented in a thickness direction of the thermal conductive layer; and an adhesion layer that includes a resin component and a thermal conductive filler containing a first thermal conductive filler having an average particle size of 500 nm or less and that is located at least at one portion of a main surface of the thermal conductive layer.

### TECHNICAL FIELD

The present disclosure relates to a thermal conductive sheet, a heat dissipating device, and a method of producing a thermal conductive sheet.

### BACKGROUND ART

In recent years, the amount of heat generation has increased due to an increase in density of mounting of wiring and electronic components in semiconductor packages with multi-layer wiring boards, the amount of heat generation per unit area has increased due to an increase in the integration of semiconductor elements, and heat dissipation from semiconductor packages has been desired.

Heat dissipating devices are generally simply used which dissipate heat with thermal conductive grease or thermal conductive sheets sandwiched between and allowed to closely adhere to heat generators such as semiconductor packages and heat dissipators such as aluminum and copper. Thermal conductive sheets are usually more excellent in workability during the assembly of heat dissipating devices than thermal conductive grease.

In recent years, chips in CPUs (Central Processing Units) have likely increased in size due to multicore and multichip. The compression bonding pressure between CPUs as heat generators and heat dissipators has likely decreased. Therefore, thermal conductive sheets are demanded to have flexibility during compression bonding. Thermal conductive sheets are also demanded to be excellent in thermal conductive properties so that thermal conductive sheets are low in thermal resistance even in the case of being increased in thickness thereof due to chip steps.

Resin sheets into which thermal conductive fillers are filled are also known as thermal conductive sheets. Various resin sheets in which inorganic particles high in thermal conductive properties are selected as thermal conductive fillers and such inorganic particles are oriented perpendicular to sheet surfaces are proposed as resin sheets into which thermal conductive fillers are filled and which are excellent in thermal conductive properties.

For example, a thermal conductive sheet in which a thermal conductive filler (boron nitride) is oriented substantially perpendicular to a sheet surface (see, for example, Patent Document 1), and a thermal conductive sheet having a structure in which a carbon fiber dispersed in a gel-like substance is oriented perpendicular to a sheet surface (see, for example, Patent Document 2) are proposed.

### CITATION LIST

### Patent Document

Patent Document 1: Japanese Patent Application Laid-Open (JP-A) No. 2002-26202
Patent Document 2: JP-A No. 2001-250894

### SUMMARY OF INVENTION

### Technical Problem

Patent Document 1 and Patent Document 2 each have studied a method of suppressing thermal resistance by orienting a thermal conductive filler, a carbon fiber, or the like in a direction perpendicular to a sheet surface. A thermal conductive sheet is demanded to be further reduced in thermal resistance in order to deal with an increase in amount of heat generation according to increases in semiconductor performance and size. Therefore, it is preferable to attempt a reduction in thermal resistance also in consideration of any other procedure than the orientation of a thermal conductive filler, a carbon fiber, or the like included in such a thermal conductive sheet.

An object of one aspect of the present invention is to provide a thermal conductive sheet low in thermal resistance, a heat dissipating device including the same, and a method of producing a thermal conductive sheet, in which the method can produce a thermal conductive sheet low in thermal resistance.

### Solution to Problem

Specific solutions for solving the above problems include the following aspects.

<1> A thermal conductive sheet, including:
a thermal conductive layer containing at least one graphite particle (A) selected from the group consisting of a scale-like particle, an ellipsoidal particle, and a rod-like particle, in which in a case of the scale-like particle, a plane direction of the scale-like particle is oriented in a thickness direction of the thermal conductive layer, in a case of the ellipsoidal particle, a longitudinal direction of the ellipsoidal particle is oriented in the thickness direction of the thermal conductive layer, and in a case of the rod-like particle, a longitudinal direction of the rod-like particle is oriented in the thickness direction of the thermal conductive layer; and
an adhesion layer that includes a resin component and a thermal conductive filler containing a first thermal conductive filler having an average particle size of 500 nm or less and that is located at least at one portion of a main surface of the thermal conductive layer.
   <2 The thermal conductive sheet according to <1>, wherein the resin component includes at least one selected from the group consisting of a curable resin component, a pressure-sensitive adhesive resin component, and a thermoplastic resin component.
   <3> The thermal conductive sheet according to <2>, wherein the resin component is a curable resin component and the adhesion layer is in a semi-cured state.
   <4> The thermal conductive sheet according to any one of <1> to <3>, wherein the resin component includes a thermoplastic resin component.
   <5> The thermal conductive sheet according to any one of <1> to <4>, wherein the thermoplastic resin component includes at least one selected from the group consisting of a thermoplastic epoxy resin, a phenoxy resin, and a saturated polyester.
   <6> The thermal conductive sheet according to any one of <1> to <4>, wherein the thermoplastic resin component includes a phenoxy resin and a saturated polyester.
   <7> The thermal conductive sheet according to <6>, wherein a content of the phenoxy resin is from 50% by mass to 90% by mass with respect to a total amount of the thermoplastic resin component and a content of the saturated polyester is from 10% by mass to 50% by mass with respect to the total amount of the thermoplastic resin component.
   <8> The thermal conductive sheet according to any one of <1> to <7>, wherein the thermal conductive filler is a particle of at least one selected from the group consisting of silver, copper, aluminum, aluminum oxide, aluminum hydroxide, magnesium oxide, beryllium oxide, boron nitride, aluminum nitride, silicon nitride, silicon carbide, silicon dioxide, aluminum fluoride, calcium fluoride, and zinc oxide.
   <9> The thermal conductive sheet according to <8>, wherein the thermal conductive filler is a silver particle.
   <10> The thermal conductive sheet according to any one of <1> to <9>, wherein a content of the thermal conductive filler is from 70% by mass to 99% by mass with respect to a total amount of the adhesion layer.
   <11> The thermal conductive sheet according to any one of <1> to <10>, wherein an average thickness of the adhesion layer is from 2 μm to 50 μm.
   <12> The thermal conductive sheet according to any one of <1> to <11>, wherein the thermal conductive filler further includes a second thermal conductive filler having an average particle size of from 1 μm to 10 μm.
   <13> The thermal conductive sheet according to <12>, wherein the first thermal conductive filler and the second thermal conductive filler are silver particles.
   <14> The thermal conductive sheet according to any one of <1> to <13>, wherein a content of the first thermal conductive filler is 20% by mass or more with respect to a total amount of the thermal conductive filler.
   <15> A heat dissipating device including a heat generator, a heat dissipator, and the thermal conductive sheet according to any one of <1> to <14>, in which the thermal conductive sheet is placed between the heat generator and the heat dissipator,
wherein the adhesion layer is located at least at one portion of at least one main surface located at a heat generator side or a main surface located at a heat dissipator side of the thermal conductive layer.
   <16> A heat dissipating device including a heat generator, a heat dissipator, and the thermal conductive sheet according to any one of <1> to <14>, in which the thermal conductive sheet is placed between the heat generator and the heat dissipator, wherein
a porosity calculated as a proportion of an area of a gas region with respect to an area of a measurement region is from 0% to 25% in at least one of an interface between the heat generator and the thermal conductive sheet or an interface between the heat dissipator and the thermal conductive sheet.
   <17> A method of producing the thermal conductive sheet according to any one of <1> to <14>,
wherein the method includes
a step of preparing a composition containing the graphite particle (A),
a step of forming the thermal conductive layer with the composition, and
a step of forming the adhesion layer at least at one portion of the main surface of the thermal conductive layer.

### Advantageous Effect of Invention

According to the disclosure, it is possible to provide a thermal conductive sheet low in thermal resistance, a heat dissipating device including the same, and a method of producing a thermal conductive sheet, in which the method can produce a thermal conductive sheet low in thermal resistance.

### BRIEF DESCRIPTION OF DRAWINGS

FIG. 1 A schematic configuration view of a thermal conductive sheet according to one embodiment of the invention.

FIG. 2 A schematic cross-sectional view of a heat dissipating device in which a heat generator is a semiconductor chip and a heat dissipator is a heat spreader, according to one embodiment of the invention.

FIG. 3 A schematic configuration diagram of a thermal conductive sheet incorporated in a heat dissipating device according to one embodiment of the invention.

### DESCRIPTION OF EMBODIMENTS

Hereinafter, modes for carrying out the invention are described. However, the invention is not limited to the following embodiments. In the following embodiments, constituent components (also including elemental steps and the like) are not essential except as particularly clearly specified. The same also applies to any numerical value and any range thereof, and the invention is not intended to be restricted.

The word “step” in the disclosure includes not only an independent step from other steps, but also any step as long as such any step achieves the object of the relevant step even in a case in which such any step cannot be distinguished from other steps.

A numerical value range indicated with “(from) . . . to . . . ” in the disclosure includes respective numerical values described before and after “to” as the minimum value and the maximum value.

The upper limit value or the lower limit value described in one numerical value range as a numerical value range described stepwise may be replaced with the upper limit value or the lower limit value of any other numerical value range described stepwise in the disclosure. The upper limit value or the lower limit value of a numerical value range as a numerical value range described in the disclosure may be replaced with any value indicated in Examples.

Each component may include a plurality of relevant substances corresponding such each component in the disclosure. In a case in which a plurality of substances corresponding to each component is present in a composition, the content of such each component means the total content of the plurality of substances present in the composition, unless particularly noted.

A particle corresponding to each component may include a plurality of such particles in the disclosure. In a case in which a plurality of particles corresponding to each component is present in a composition, the particle size of such each component means the value for a mixture of the plurality of particles present in the composition, unless particularly noted.

The word “layer” or “film” in the disclosure includes not only a case in which the layer or film is formed on the whole of a region in which the layer or film is present, but also a case in which the layer or film is formed on only one portion of the region in observation of the region.

The word “layered” in the disclosure indicates that layers are layered, in which two or more layers may be connected or two or more layers are detachable.

### [Thermal Conductive Sheet]

The thermal conductive sheet of the disclosure includes: a thermal conductive layer containing at least one graphite particle (A) selected from the group consisting of a scale-like particle, an ellipsoidal particle, and a rod-like particle, in which in a case of the scale-like particle, the plane direction of the scale-like particle is oriented in the thickness direction of the thermal conductive layer, in a case of the ellipsoidal particle, the longitudinal direction of the ellipsoidal particle is oriented in the thickness direction of the thermal conductive layer, and in a case of the rod-like particle, the longitudinal direction of the rod-like particle is oriented in the thickness direction of the thermal conductive layer; and an adhesion layer that includes a resin component and a thermal conductive filler containing a first thermal conductive filler having an average particle size of 500 nm or less and that is located at least at one portion of a main surface of the thermal conductive layer.

The thermal conductive sheet of the disclosure includes the thermal conductive layer in which the graphite particle (A) is oriented in the thickness direction, and thus is considered to be excellent in thermal conductive properties in the thickness direction and exhibits low thermal resistance.

Furthermore, the thermal conductive sheet includes not only the thermal conductive layer containing the graphite particle (A), but also the adhesion layer, and thus is considered to exhibit lower thermal resistance. The reason for this is presumed as follows. The disclosure is not limited to the following presumption. Any asperity is present on a surface of the thermal conductive sheet in which the graphite particle (A) is oriented in the thickness direction, the surface being in contact with an adherend, and most of thermal resistance is derived from resistance (also referred to as “contact thermal resistance”) by a gap generated due to contact between the thermal conductive sheet and the adherend, for example, a heat generator or a heat dissipator, in contact with the thermal conductive sheet. The thermal conductive sheet of the disclosure includes an adhesion layer including a resin component and a thermal conductive filler, placed at least at one portion of a main surface of the thermal conductive layer, whereby the adhesion layer is, for example, softened or deformed due to heat, pressure, or the like during heating compression bonding of the thermal conductive sheet and an adherend such as a heat generator or a heat dissipator. The adhesion layer is, for example, softened or deformed, whereby a gap (for example, a gap derived from the asperity of the thermal conductive sheet) generated during heating compression bonding of the thermal conductive sheet and the adherend is embedded with the adhesion layer. Thus, not only such a gap between the thermal conductive sheet and the adherend can be reduced, but also the thermal conductive sheet and the adherend can be allowed to closely adhere with the adhesion layer being interposed, and therefore contact thermal resistance is significantly reduced.

Also in a case in which any asperity is present on a surface of an adherend such as a heat generator or a heat dissipator, contact thermal resistance is easily caused. In this case, it is difficult to reduce such thermal resistance by a method of adjusting orientation of the thermal conductive filler or the like included in the thermal conductive sheet. In this regard, the thermal conductive sheet of the disclosure can be used to allow for close adhesion of the thermal conductive sheet and an adherend in which any asperity is present on a surface thereof, with the adhesion layer being interposed. Here, a gap (for example, a gap derived from the asperity of the adherend) generated during heating compression bonding of the thermal conductive sheet and the adherend is embedded with the adhesion layer, and therefore contact thermal resistance is significantly reduced.

The thermal conductive filler further includes a first thermal conductive filler having an average particle size of 500 nm or less. The first thermal conductive filler is included, whereby a thermal conductive path by sintering of the thermal conductive filler is easily formed even in a lower-temperature heating condition (for example, 180° C. or less) during adhesion of the adherend and the thermal conductive sheet, and thermal conductive properties of the thermal conductive sheet tend to be enhanced to provide lower thermal resistance.

The thermal conductive layer included in the thermal conductive sheet of the disclosure includes at least the graphite particle (A), and may include a component described later as long as the effects of the disclosure are exerted. Hereinafter, each material used in the thermal conductive layer in the disclosure is described.

### <Graphite Particle (A)>

The thermal conductive layer included in the thermal conductive sheet contains a graphite particle (A). It is considered that the graphite particle (A) mainly functions as a high-thermal conductive filler. The graphite particle (A) is at least one selected from the group consisting of a scale-like particle, an ellipsoidal particle, and a rod-like particle. In a case in which the graphite particle (A) is the scale-like particle, the plane direction of the scale-like particle is oriented in the thickness direction of the thermal conductive layer, in a case in which the graphite particle is the ellipsoidal particle, the longitudinal direction of the ellipsoidal particle is oriented in the thickness direction of the thermal conductive layer, and in a case in which the graphite particle is the rod-like particle, the longitudinal direction of the rod-like particle is oriented in the thickness direction of the thermal conductive layer. It is preferable that, in a case in which the graphite particle (A) is the scale-like particle, a six-membered ring plane in a crystal thereof is oriented in the plane direction, in a case in which the graphite particle is the ellipsoidal particle, the six-membered ring plane thereof is oriented in the longitudinal direction, and in a case in which the graphite particle is the rod-like particle, the six-membered ring plane thereof is oriented in the longitudinal direction. The six-membered ring plane is a plane in which a six-membered ring is formed in the hexagonal system, and means the (0001) crystal plane.

The shape of the graphite particle (A) is more preferably a scale-like shape. The scale-like graphite particle is selected, whereby thermal conductive properties tend to be more enhanced. The reason for this can be considered because, for example, the scale-like graphite particle is more easily oriented in a predetermined direction in the thermal conductive layer.

Whether or not the six-membered ring plane in a crystal of the graphite particle (A) is oriented in the plane direction of the scale-like particle, the longitudinal direction of the ellipsoidal particle, or the longitudinal direction of the rod-like particle can be confirmed by X-ray diffraction measurement. The orientation direction of the six-membered ring plane in a crystal of the graphite particle (A) is specifically confirmed by the following method.

First, a sample sheet for measurement is produced in which the plane direction of the scale-like particle, the longitudinal direction of the ellipsoidal particle, or the longitudinal direction of the rod-like particle, of the graphite particle (A), is oriented along with the plane direction of the sheet. Examples of a specific method of producing the sample sheet for measurement include the following method.

A mixture of a resin and the graphite particle (A) in an amount of 10% by volume or more with respect to the resin is formed into a sheet. The “resin” used here is not particularly limited as long as it is a material which does not exhibit a peak interfering with X-ray diffraction and which can form a sheet product. Specifically, an amorphous resin serving as a binder and thus having cohesion force, such as acrylic rubber, NBR (acrylonitrile/butadiene rubber), or SIBS (styrene-isobutylene-styrene copolymer), can be used.

The sheet of the mixture is pressed so as to have a thickness of one-tenth or less of the original thickness, and a plurality of such sheets pressed is layered to form a laminated body. An operation for further squashing the laminated body to a thickness of one-tenth or less is repeated three times or more to obtain a sample sheet for measurement. This operation allows the graphite particle (A) in the sample sheet for measurement to be in a state in which the plane direction in the case of the scale-like particle, the longitudinal direction in the case of the ellipsoidal particle, or the longitudinal direction in the case of the rod-like particle is oriented along with the plane direction of the sample sheet for measurement.

A surface of the sample sheet for measurement, produced as above, is subjected to X-ray diffraction measurement. The height H₁ of a peak corresponding to the (110) plane of graphite, appearing around 2θ=77°, and the height H₂ of a peak corresponding to the (002) plane of graphite, appearing around 2θ=27°, are measured. The value obtained by dividing H₁ by H₂ is from 0 to 0.02 in the sample sheet for measurement, thus produced.

Thus, the “six-membered ring plane in a crystal of the graphite particle (A) is oriented in the plane direction in the case of the scale-like particle, the longitudinal direction in the case of the ellipsoidal particle, or the longitudinal direction in the case of the rod-like particle” refers to a state in which the value obtained by dividing the height of a peak corresponding to the (110) plane of the graphite particle (A), appearing around 2θ=77°, by the height of peak corresponding to the (002) plane of the graphite particle (A), appearing around 2θ=27°, in X-ray diffraction measurement performed with respect to a surface of a sheet containing the graphite particle (A), is from 0 to 0.02.

X-ray diffraction measurement in the disclosure is performed in the following conditions.
Apparatus: for example, “D8DISCOVER” manufactured by Bruker AXS LLC
X-ray source: CuKα (wavelength 1.5406 nm), 40 kV, 40 mA
Step (measurement step size): 0.01°
Step time: 720 sec

Here, “the plane direction in the case of the scale-like particle as the graphite particle, the longitudinal direction in the case of the ellipsoidal particle as the graphite particle, and the longitudinal direction in the case of the rod-like particle as the graphite particle are each oriented in the thickness direction of the thermal conductive layer” means that the angle (hereinafter, also referred to as “orientation angle”) between each of the plane direction in the case of the scale-like particle, the longitudinal direction in the case of the ellipsoidal particle, and the longitudinal direction in the case of the rod-like particle, and a surface (main surface) of the thermal conductive layer is 60° or more. The orientation angle is preferably 80° or more, more preferably 85° or more, still more preferably 88° or more.

The orientation angle is an average value in observation of a cross section of the thermal conductive layer with SEM (scanning electron microscope) and measurement of the angle (orientation angle) between each of the plane direction in the case of the scale-like particle, the longitudinal direction in the case of the ellipsoidal particle, and the longitudinal direction in the case of the rod-like particle, and a surface (main surface) of the thermal conductive layer with respect to each of any 50 of such graphite particles (A).

The particle size of the graphite particle (A) is not particularly limited. The average particle size of the graphite particle (A) is preferably from one-half the average thickness to the average thickness of the thermal conductive layer, in terms of the mass average particle size. In a case in which the mass average particle size of the graphite particle (A) is equal to or more than one-half the average thickness of the thermal conductive layer, an efficient thermal conductive path tends to be formed in the thermal conductive layer, thereby resulting in an In a case in which the mass average particle size of the enhancement in thermal conductivity.

graphite particle (A) is equal to or less than the average thickness of the thermal conductive layer, the graphite particle (A) tends to be inhibited from being protruded from the surface of the thermal conductive layer, thereby allowing the surface of the thermal conductive layer to be excellent in close adhesiveness.

The method of producing the thermal conductive layer so that the plane direction in the case of the scale-like particle, a longer axis in the case of the ellipsoidal particle, and the longitudinal direction in the case of the rod-like particle are each oriented in the thickness direction is not particularly limited, and the method described in, for example, JP-A No. 2008-280496 can be used. Specifically, a method (hereinafter, also referred to as “layering slicing method”) can be used which includes producing a sheet with a composition, layering the sheet to produce a laminated body, and slicing a side edge surface of the laminated body (for example, at an angle of from 0° to 30° against the normal line coming from a main surface of the laminated body).

In a case in which the layering slicing method is used, the particle size of the graphite particle (A) used as a raw material is preferably one-half times or more the average thickness of the thermal conductive layer, in terms of the mass average particle size, or may exceed the average thickness. The reason why the particle size of the graphite particle (A) used as a raw material may exceed the average thickness of the thermal conductive layer is, for example, because, even in a case in which the graphite particle (A), which has a particle size exceeding the average thickness of the thermal conductive layer, is included, the graphite particle (A) is together sliced to form the thermal conductive layer, thereby resulting in no protrusion of the graphite particle (A) from the surface of the thermal conductive layer. The reason is also because, in a case in which the graphite particle (A) is thus together sliced, the graphite particle (A), which penetrates in the thickness direction of the thermal conductive layer, tends to much occur, thereby leading to formation of an extremely efficient thermal conductive path and more enhancements in thermal conductive properties.

In a case in which the layering slicing method is used, the particle size of the graphite particle (A) used as a raw material, in terms of the average particle size, is more preferably from 1 time to 5 times, still more preferably from 2 times to 4 times the average thickness of the thermal conductive layer mass. In a case in which the mass average particle size of the graphite particle (A) is 1 time or more the average thickness of the thermal conductive layer, a further efficient thermal conductive path is formed, and thermal conductive properties are more enhanced. In a case in which the mass average particle size is 5 times or less the average thickness of the thermal conductive layer, the area of the graphite particle (A) occupying a surface portion is inhibited from being too large, and deterioration in close adhesiveness can be suppressed.

The mass average particle size (D50) of the graphite particle (A) is measured with a laser diffraction type particle size distribution apparatus (for example, “Microtrac series MT3300” manufactured by Nikkiso Co., Ltd.) adapted to a laser diffraction-scattering method, and corresponds to a particle size at a mass accumulation of 50% in a case in which a mass cumulative particle size distribution curve is drawn from the smaller particle size side.

The thermal conductive layer may include a graphite particle other than the scale-like particle, the ellipsoidal particle, and the rod-like particle, such as a spherical graphite particle, an artificial graphite particle, a thinned graphite particle, an acid-treated graphite particle, an expanded graphite particle, or a carbon fiber flake.

The graphite particle (A) is preferably the scale-like particle from the viewpoint of easily providing a scale having a high degree of crystallization and a large particle size, and is preferably a scale-like expanded graphite particle obtained by grinding sheet-shaped expanded graphite.

The content of the graphite particle (A) in the thermal conductive layer is, for example, preferably from 15% by volume to 50% by volume, more preferably from 20% by volume to 45% by volume, still more preferably from 25% by volume to 40% by volume, from the viewpoint of the balance between thermal conductive properties and close adhesiveness.

In a case in which the content of the graphite particle (A) is 15% by volume or more, thermal conductive properties tend to be enhanced. In a case in which the content of the graphite particle (A) is 50% by volume or less, deterioration of pressure-sensitive adhesiveness and close adhesiveness tends to be able to be suppressed.

In a case in which the thermal conductive layer contains a graphite particle other than the scale-like particle, the ellipsoidal particle, and the rod-like particle, the content of the entire graphite particle is preferably in the above range.

The content (% by volume) of the graphite particle (A) is a value determined by the following Formula.

$$Content rate ( \% by volume ) of graphite particle ( A ) = [ ( Aw / Ad ) / \{ ( Aw / Ad ) + ( Xw / Xd ) \} ] \times 100$$

Aw: Mass compositional ratio (% by mass) of graphite particle (A)
Xw: Mass compositional ratio (% by mass) of any other component
Ad: Density (calculated with 2.1 as Ad in the disclosure) of graphite particle (A)
Xd: Density of any other component
   <Component (B) that is Liquid at 25° C.>

The thermal conductive layer included in the thermal conductive sheet of the disclosure may contain a component (hereinafter, also referred to as “liquid component (B)”) that is liquid at 25° C. In the disclosure, “liquid at 25° C.” means a substance which exhibits fluidity and viscous behavior at 25° C. and in which the viscosity as an index indicating viscous behavior is from 0.0001 Pa·s to 1000 Pa's at 25° C. In the disclosure, “viscosity” is defined as a value measured at a shear rate of 5.0 s-1 with a rheometer at 25° C. Specifically, “viscosity” is measured as a shear viscosity at a temperature of 25° C. with a rotary shear viscometer equipped with a cone plate (diameter 40 mm, cone angle) 0°.

The viscosity at 25° C. of the liquid component (B) is preferably from 0.001 Pa·s to 100 Pa·s, more preferably from 0.01 Pa's to 10 Pa·s.

The liquid component (B) is not particularly limited as long as it is liquid at 25° C., and is preferably a polymer compound (polymer). Examples of the liquid component (B) include polybutene, polyisoprene, polysulfide, acrylonitrile rubber, silicone rubber, a hydrocarbon resin, a terpene resin, and an acrylic resin. In particular, the liquid component (B) preferably includes polybutene from the viewpoint of heat resistance. The liquid component (B) may be used singly, or in combination of two or more kinds thereof.

Here, the polybutene refers to a polymer obtained by polymerizing isobutene or n-butene. The polybutene also encompasses a polymer obtained by copolymerizing isobutene and n-butene. The polybutene refers to a polymer having a structure unit represented by “—CH₂—C(CH₃)₂-” or “—CH₂—CH(CH₂CH₃)—” in terms of the structure. The polybutene may also be referred to as polyisobutylene. The polybutene is not particularly limited with respect to any other structure as long as it contains the structure.

Examples of the polybutene include a homopolymer of butene, and a copolymer of butene and any other monomer component. Examples of the copolymer with any other monomer component include a copolymer of isobutene and styrene or a copolymer of isobutene and ethylene. The copolymer may be any of a random copolymer, a block copolymer, or a graft copolymer.

Examples of the polybutene include “NOF polybutene (TM). EMAWET (registered trademark)” of NOF Corporation, “Nisseki Polybutene” of JXTG Energy, “Tetrax” of JXTG Energy, “Himol” of JXTG Energy, and “polyisobutylene” of TOMOE Engineering Co., Ltd.

It is considered that the liquid component (B) is excellent in heat resistance and humidity resistance and mainly functions as, for example, both a stress relaxing agent and a tackifier. A hot-melt agent (D) described later is used in combination, thereby resulting in a tendency to allow for more increases in cohesion force and fluidity during heating.

The content of the liquid component (B) in the thermal conductive layer is preferably from 10% by volume to 55% by volume, more preferably from 15% by volume to 50% by volume, still more preferably from 20% by volume to 50% by volume from the viewpoint of more enhancements in pressure-sensitive adhesion force, close adhesiveness, sheet strength, hydrolysis resistance, and the like.

In a case in which the content of the liquid component (B) is 10% by volume or more, pressure-sensitive adhesiveness and close adhesiveness tend to be more enhanced. In a case in which the content of the liquid component (B) is 55% by volume or less, deterioration of sheet strength and thermal conductive properties tends to be able to be more effectively suppressed.

### <Acrylic Acid Ester-Based Polymer (C)>

The thermal conductive layer included in the thermal conductive sheet may contain an acrylic acid ester-based polymer (C). It is considered that the acrylic acid ester-based polymer (C) mainly functions as, for example, both a tackifier and an elasticity improver that restores thickness for following to warpage.

The acrylic acid ester-based polymer (C) used here is suitably, for example, an acrylic acid ester-based polymer (so-called acrylic rubber) in which butyl acrylate, ethyl acrylate, acrylonitrile, acrylic acid, glycidyl methacrylate, 2-ethylhexyl acrylate, or the like is a main raw material and, if necessary, methyl acrylate or the like is copolymerized. The acrylic acid ester-based polymer (C) may be used singly, or in combination of two or more kinds thereof.

The weight average molecular weight of the acrylic acid ester-based polymer (C) is preferably from 100,000 to 1,000,000, more preferably from 250,000 to 700,000, still more preferably from 400,000 to 600,000. In a case in which the weight average molecular weight is 100,000 or more, film strength tends to be excellent, and in a case in which the weight average molecular weight is 1,000,000 or less, flexibility tends to be excellent.

The weight average molecular weight can be measured by use of a calibration curve of standard polystyrene according to gel permeation chromatography.

The glass transition temperature (Tg) of the acrylic acid ester-based polymer (C) is preferably 20° C. or less, more preferably from −70° C. to 0° C., still more preferably from −50° C. to −20° C. In a case in which the glass transition temperature is 20° C. or less, flexibility and pressure-sensitive adhesiveness tend to be excellent.

The glass transition temperature (Tg) can be calculated from tan δ derived by dynamic viscoelasticity measurement with tension.

The acrylic acid ester-based polymer (C) may be allowed to be present in the entire thermal conductive layer by internal addition, or may be allowed to be locally present on a surface by coating or impregnation of a surface. In particular, coating of one surface or impregnation of one surface is preferred because strong tackiness can be imparted to only one surface and thus a sheet favorable in handling properties is obtained.

The content of the acrylic acid ester-based polymer (C) in the thermal conductive layer is preferably 3% by volume to 25% by volume, more preferably 5% by volume to 20% by volume, still more preferably 7% by volume to 15% by volume.

### <Hot-Melt Agent (D)>

The thermal conductive layer included in the thermal conductive sheet may contain a hot-melt agent (D). The hot-melt agent (D) has the effects of enhancing strength of the thermal conductive layer, and enhancing fluidity during heating.

Examples of the hot-melt agent (D) include an aromatic petroleum resin, a terpene phenol resin, and a cyclopentadiene-based petroleum resin. The hot-melt agent (D) may be a hydrogenated aromatic petroleum resin or a hydrogenated terpene phenol resin. The hot-melt agent (D) may be used singly, or in combination of two or more kinds thereof.

In particular, in a case in which the polybutene is used as the liquid component (B), the hot-melt agent (D) preferably includes at least one selected from the group consisting of a hydrogenated aromatic petroleum resin and a hydrogenated terpene phenol resin. Such a hot-melt agent (D) is high in stability and is excellent in compatibility with the polybutene, and therefore the thermal conductive layer, which is formed from such a hot-melt agent, tends to be able to achieve more excellent thermal conductive properties, flexibility, and handling properties.

Examples of a commercially available hydrogenated aromatic petroleum resin include “ARKON” of Arakawa Chemical Industries, Ltd., and “I-MARV” of Idemitsu Kosan Co., Ltd. Examples of a commercially available hydrogenated terpene phenol resin include “CLEARON” of Yasuhara Chemical Co., Ltd. Examples of a commercially available cyclopentadiene-based petroleum resin include “Quintone” of Zeon Corporation and “MARUKARETZ” of Maruzen Petrochemical Co., Ltd.

The hot-melt agent (D) preferably is solid at 25° C. and has a softening temperature of from 40° C. to 150° C. In a case in which a thermoplastic resin is used as the hot-melt agent (D), softening fluidity during thermal compression bonding is enhanced, thereby resulting in a tendency to enhance close adhesiveness. In a case in which the softening temperature is 40° C. or more, cohesion force around room temperature can be kept, thereby resulting in a tendency to easily impart required sheet strength and impart excellent handling properties. In a case in which the softening temperature is 150° C. or less, softening fluidity during thermal compression bonding is increased, thereby resulting in a tendency to enhance close adhesiveness. The softening temperature is more preferably from 60° C. to 120° C. The softening temperature is measured by a ring-and-ball method (JIS K 2207:1996).

The content of the hot-melt agent (D) in the thermal conductive layer is preferably from 3% by volume to 25% by volume, more preferably from 5% by volume to 20% by volume, still more preferably from 5% by volume to 15% by volume from the viewpoint of enhancements in pressure-sensitive adhesion force, close adhesiveness, sheet strength, and the like.

In a case in which the content of the hot-melt agent (D) is 3% by volume or more, pressure-sensitive adhesion force, heating fluidity, sheet strength, and the like tend to be sufficient, and in a case in which the content is 25% by volume or less, flexibility tends to be sufficient, thereby imparting excellent handling properties and thermal cycle resistance.

### <Antioxidant (E)>

The thermal conductive layer included in the thermal conductive sheet may contain an antioxidant (E), for example, for the purpose of imparting heat stability at high temperature. Examples of the antioxidant (E) include a phenol-based antioxidant, a phosphorus-based antioxidant, an amine-based antioxidant, a sulfur-based antioxidant, a hydrazine-based antioxidant, and an amide-based antioxidant. The antioxidant (E) may be appropriately selected depending on, for example, a temperature condition used, and a phenol-based antioxidant is more preferred. The antioxidant (E) may be used singly, or in combination of two or more kinds thereof.

Examples of a commercially available phenol-based antioxidant include ADEKA STAB AO-50, ADEKA STAB AO-60, and ADEKA STAB AO-80 of ADEKA CORPORATION.

The content of the antioxidant (E) in the thermal conductive layer is not particularly limited, and is preferably from 0.1% by volume to 5% by volume, more preferably from 0.2% by volume to 3% by volume, still more preferably from 0.3% by volume to 1% by volume. In a case in which the content of the antioxidant (E) is 0.1% by volume or more, the antioxidation effect tends to be sufficiently obtained. In a case in which the content of the antioxidant (E) is 5% by volume or less, strength of the thermal conductive layer tends to be able to be inhibited from being reduced.

### <Other Components>

The thermal conductive layer included in the thermal conductive sheet may contain any other component than the graphite particle (A), the liquid component (B), the acrylic acid ester-based polymer (C), the hot-melt agent (D), and the antioxidant (E), depending on the objects. For example, the thermal conductive layer may contain a flame retardant from the viewpoint of flame retardance. The flame retardant is not particularly limited, and can be appropriately selected from flame retardants usually used. Examples include a red phosphorus-based flame retardant and a phosphoric acid ester-based flame retardant. In particular, a phosphoric acid ester-based flame retardant is preferred from the viewpoint that safety is excellent and close adhesiveness enhances by the plasticizing effect.

The red phosphorus-based flame retardant used here may be one that is variously coated or is formed into a master batch in order to enhance safety or stability, in addition to a pure red phosphorus particle. Specific examples include Novared, Novaexcel, Novaquel, and Novapellet (all are trade names) of RIN KAGAKU KOGYO Co., Ltd.

Examples of the phosphoric acid ester-based flame retardant include aliphatic phosphoric acid esters such as trimethyl phosphate, triethyl phosphate, and tributyl phosphate; aromatic phosphoric acid esters such as triphenyl phosphate, tricresyl phosphate, cresyl diphenyl phosphate, trixylenyl phosphate, cresyl di-2,6-xylenyl phosphate, tris (t-butylated phenyl) phosphate, tris (isopropylated phenyl) phosphate, and triaryl isopropyl phosphate; and aromatic fused phosphoric acid esters such as resorcinol bisdiphenyl phosphate, bisphenol A bis(diphenyl phosphate), and resorcinol bisdixylenyl phosphate.

In particular, bisphenol A bis(diphenyl phosphate) is preferred from the viewpoint that it is excellent in hydrolysis resistance and is excellent in the effect of enhancing close adhesiveness by the plasticizing effect.

The content of the flame retardant in the thermal conductive layer is not limited, can be an amount allowing flame retardance to be exhibited, is preferably about 30% by volume or less or less, and is preferably 20% by volume or less from the viewpoint of suppression of deterioration in thermal resistance due to leakage of a flame retardant component to a surface of the thermal conductive layer.

The average thickness of the thermal conductive layer is not particularly limited, and can be appropriately selected depending on the objects. The thickness of the thermal conductive layer can be appropriately selected depending on the specification of a semiconductor package or the like used. As the thickness is smaller, thermal resistance tends to be reduced, and as the thickness is larger, following properties to warpage tend to be enhanced. The average thickness of the thermal conductive layer may be from 20 μm to 3000 μm, and is preferably from 30 μm to 500 μm, more preferably from 50 to 400 μm from the viewpoint of thermal conductive properties and close adhesiveness.

The average thickness of the thermal conductive layer is provided as the arithmetic average value in observation of a cross section of a measurement subject with an electron microscope or in measurement of respective thicknesses at random three positions with a micrometer.

### <Adhesion Layer>

The thermal conductive sheet of the disclosure includes an adhesion layer that includes a resin component and a thermal conductive filler containing a first thermal conductive filler having an average particle size of 500 nm or less and that is located at least at one portion of a main surface of the thermal conductive layer.

Examples of the resin component include a curable resin component, a pressure-sensitive adhesive resin component, and a thermoplastic resin component. Examples of the curable resin component include a thermosetting resin component and a photo-curable resin component. The resin component may include one or more such curable resin components, may include one or more pressure-sensitive adhesive resin components, or may include one or more thermoplastic resin components. The resin component may be a mixture of two or more kinds thereof.

Examples of the curable resin component include an epoxy resin, a phenol resin, a melamine resin, a urea resin, an unsaturated polyester resin, an alkyd resin, a urethane resin, a polyimide resin such as a bismaleimide resin, a polyamide resin, a polyamide-imide resin, a silicone resin, and a thermosetting (meth)acrylic resin. In particular, an epoxy resin is preferred from the viewpoint of close adhesiveness.

Examples of the pressure-sensitive adhesive resin component, the thermoplastic resin component, and the like include polyethylene (PE), polypropylene (PP), polycarbonate (PC), polystyrene, polyvinyl chloride, a vinyl polymer, saturated polyester, polyamide, an acrylonitrile-butadiene-styrene copolymer resin (ABS resin), a thermoplastic (meth)acrylic resin, an acrylonitrile-ethylene-propylene-diene-styrene copolymer resin (AES resin), a thermoplastic epoxy resin, phenoxy resin, and a thermoplastic elastomer. The thermoplastic resin component is used, whereby the adhesion layer is easily softened or melted by heating, and recycling properties and repair properties are excellent. The thermal conductive sheet, in which the thermoplastic resin component is used, is excellent in storage stability and can also be retained at room temperature, as compared with the thermal conductive sheet, in which the curable resin component (in particular, thermosetting resin component) is used. In particular, the thermoplastic resin component is preferably a thermoplastic epoxy resin, a phenoxy resin, or a saturated polyester from the viewpoint that a reduction in viscosity by heating can be achieved and a gap between an adherend and the thermal conductive sheet can be more reduced.

The thermoplastic resin component may include a phenoxy resin and a saturated polyester.

In a case in which the thermoplastic resin component includes a phenoxy resin and a saturated polyester, the total content of the phenoxy resin and the saturated polyester may be from 50% by mass to 100% by mass, may be from 80% by mass to 100% by mass, or may be from 90% by mass to 100% by mass with respect to 100% by mass of the thermoplastic resin component.

In a case in which the thermoplastic resin component includes a phenoxy resin and a saturated polyester, the content of the phenoxy resin may be from 50% by mass to 90% by mass, or from 60% by mass to 80% by mass with respect to the total amount of the thermoplastic resin component. The content of the saturated polyester may be from 10% by mass to 50% by mass, or from 20% by mass to 40% by mass with respect to the total amount of the thermoplastic resin component.

The thermoplastic resin component may be an amorphous thermoplastic resin, and the amorphous thermoplastic resin may be, for example, at least one of a thermoplastic epoxy resin or a phenoxy resin. The amorphous thermoplastic resin refers to a resin in which, although the resin has a melting point (Tm), an endothermic peak according to melting is not confirmed as a clear endothermic peak or the endothermic peak is very small in measurement with a differential scanning calorimeter (DSC).

The heat of fusion of the amorphous thermoplastic resin is preferably 15 J/g or less, more preferably 11 J/g or less, still more preferably 7 J/g or less, particularly preferably 4 J/g or less, and the melting peak most preferably corresponds to a detection limit or less.

The heat of fusion is calculated from the area of the endothermic peak in DSC (differential scanning calorimeter), and the mass of the thermoplastic resin component. The heat of fusion is here calculated with the mass of the thermoplastic resin component excluding a component included in the adhesion layer, for example, the thermal conductive filler.

For example, the heat of fusion can be determined as follows.

First, from 2 mg to 10 mg of a specimen is weighed, placed in an aluminum pan, and heated to 200° C. or more at 10° C./min with DSC (for example, DSC8231 manufactured by Rigaku Corporation), thereby obtaining a DSC curve. Next, the heat of fusion is calculated from the area of an endothermic peak in melting, as determined from the DSC curve, and the weighing value.

The thermoplastic epoxy resin is a polymer of (a) a bifunctional epoxy resin monomer or oligomer and (b) a bifunctional compound containing the same or different two functional groups selected from the group consisting of a phenolic hydroxyl group, a carboxyl group, a mercapto group, an isocyanate group, and a cyanate ester group. The polymer can be produced by heating the component (a) and the component (b) in the presence of a catalyst such as an imidazole catalyst.

The bifunctional epoxy resin monomer or oligomer (a) refers to an epoxy resin monomer or oligomer having two epoxy groups in its molecule.

Specific examples of the component (a) include a bisphenol A-type epoxy resin, a bisphenol F-type epoxy resin, a bifunctional phenol novolac-type epoxy resin, a bisphenol AD-type epoxy resin, a biphenyl-type epoxy resin, a bifunctional naphthalene-type epoxy resin, a bifunctional alicyclic epoxy resin, a bifunctional glycidyl ester-type epoxy resin (for example, diglycidyl phthalate, diglycidyl tetrahydrophthalate, or dimer acid diglycidyl ester), a bifunctional glycidyl amine-type epoxy resin (for example, diglycidyl aniline or diglycidyl toluidine), a bifunctional heterocyclic epoxy resin, a bifunctional diarylsulfone-type epoxy resin, a hydroquinone-type epoxy resin (for example, hydroquinone diglycidyl ether, 2,5-di-tert-butylhydroquinone diglycidyl ether, or resorcin diglycidyl ether), a bifunctional alkylene glycidyl ether-based compound (for example, butanediol diglycidyl ether, butenediol diglycidyl ether, or butynediol diglycidyl ether), a bifunctional glycidyl group-containing hydantoin compound (for example, 1,3-diglycidyl-5,5-dialkylhydantoin or 1-glycidyl-3-(glycidoxyalkyl)-5,5-dialkylhydantoin), bifunctional glycidyl group-containing siloxane (for example, 1,3-bis (3-glycidoxypropyl)-1,1,3,3-tetramethyldisiloxane or α,β-bis (3-glycidoxypropyl) polydimethylsiloxane), and any modified product thereof. In particular, a bisphenol A-type epoxy resin, a bisphenol F-type epoxy resin, and a biphenyl-type epoxy resin are preferred in terms of reactivity and workability.

Examples of the phenol hydroxyl group-containing bifunctional compound (b) include mononuclear aromatic dihydroxy compounds each having one benzene ring, such as catechol, resorcin, and hydroquinone, bisphenol compounds such as bis(4-hydroxyphenyl) propane (bisphenol A), bis(4-hydroxyphenyl) methane (bisphenol F), bis(4-hydroxyphenyl) ethane (bisphenol AD), and bis(4-hydroxyphenyl) sulfone (bisphenol S), a compound having a fused ring, such as dihydroxynaphthalene, bifunctional phenol compounds each containing an allyl group introduced thereinto, such as diallyl resorcin, diallyl bisphenol A, and triallyl dihydroxybiphenyl, and dibutylbisphenol A.

Examples of the carboxyl group-containing bifunctional compound (b) include adipic acid, succinic acid, malonic acid, cyclohexanedicarboxylic acid, phthalic acid, isophthalic acid, and terephthalic acid.

Examples of the mercapto group-containing bifunctional compound (b) include ethylene glycol bisthioglycolate and ethylene glycol bisthiopropionate.

Examples of the isocyanate group-containing bifunctional compound (b) include diphenylmethane diisocyanate (MDI), isophorone diisocyanate (IPDI), hexamethylene diisocyanate (HMDI), and tolylene diisocyanate (TDI).

Examples of the cyanate ester group-containing bifunctional compound (b) include 2,2-bis(4-cyanatophenyl) propane, 1,1-bis(4-cyanatophenyl) ethane, and bis(4-cyanatophenyl) methane.

Among such components (b) described above, a phenol hydroxyl group-containing bifunctional compound is preferred from the viewpoint that a thermoplastic polymerized product is obtained, a bifunctional compound containing two phenolic hydroxyl groups and a bisphenol structure or biphenyl structure is preferred from the viewpoint of heat resistance and adhesiveness, and bisphenol A, bisphenol F or bisphenol S is preferred from the viewpoint of heat resistance and cost.

In a case in which the (a) is a bisphenol A-type epoxy resin, a bisphenol F-type epoxy resin, a bisphenol S-type epoxy resin, or a biphenyl-type epoxy resin and the (b) is bisphenol A, bisphenol F, or bisphenol S, a polymer obtained by polymerization of the (a) and (b) preferably has a structure in which a main chain formed with a para-phenylene structure and an ether bond that serve as a main backbone and that are linked with an alkylene group and a side chain being a hydroxyl group generated by polyaddition are placed.

Not only a linear structure including a para-phenylene backbone can increase mechanical strength of a polymer after polymerization, but also such a hydroxyl group placed as a side chain can enhance close adhesiveness. As a result, not only workability of a thermosetting resin is maintained, but also high adhesion strength can be realized.

The epoxy equivalent (molecular weight/number of epoxy groups) of the thermoplastic epoxy resin may be 1600 g/eq or more, may be 2000 g/eq or more, may be 5000 g/eq or more, or may be 9000 g/eq or more.

The epoxy equivalent of the epoxy resin is a value measured by a method according to JIS K 7236:2009.

The adhesion layer may include a phenoxy resin as the thermoplastic resin component.

The phenoxy resin is, for example, a polyhydroxy polyether synthesized from a bisphenol compound and epichlorohydrin, and has thermoplasticity.

Known phenoxy resin production methods include a method by a direct reaction of a dihydric phenol compound and epichlorohydrin, and a method by an addition polymerization reaction of diglycidyl ether of a dihydric phenol compound and the dihydric phenol compound. In the case of the direct reaction of a dihydric phenol compound and epichlorohydrin, examples of the dihydric phenol compound include phenol compounds such as bisphenol A, bisphenol F, bisphenol S, biphenol, biphenylenediol, and fluorene diphenyl; and aliphatic glycols such as ethylene glycol, propylene glycol, and diethylene glycol. In particular, bisphenol A, bisphenol F, bisphenol S, or the like is preferred from the viewpoint of cost, adhesiveness, viscosity, heat resistance, or the like. These may be used singly, or in combination of two or more kinds thereof.

The phenoxy resin preferably has a chemical structure similar to that of an epoxy resin, and preferably has a structure in which a main chain formed with a para-phenylene structure and an ether bond that serve as a main backbone and that are linked and a side chain being a hydroxyl group are placed.

The adhesion layer may include a saturated polyester as the thermoplastic resin component.

The saturated polyester may be, for example, a compound formed by a dehydration-condensation reaction of a polybasic acid component and a polyol component. For example, the saturated polyester may also be a linear saturated polyester formed from a dibasic acid component and a diol component.

Examples of the dibasic acid component include aromatic dicarboxylic acids such as ortho-phthalic acid, isophthalic acid, and terephthalic acid, alicyclic dicarboxylic acids such as hexahydrophthalic acid, tetrahydrophthalic acid, 1,3-cyclohexanedicarboxylic acid, and 1,4-cyclohexanedicarboxylic acid, aliphatic dicarboxylic acids such as oxalic acid, succinic acid, malonic acid, glutaric acid, adipic acid, pimelic acid, suberic acid, azelaic acid, sebacic acid, decanedicarboxylic acid, dodecanedicarboxylic acid, and octadecanedicarboxylic acid, or acid anhydrides or lower alcohol esters thereof.

Examples of the diol component include ethylene glycol, 1,2-propanediol, 1,3-propanediol, 1,3-butanediol, 1,4-butanediol, neopentyl glycol, pentanediol, 1,6-hexanediol, 1,8-octanediol, 1,10-decanediol, diethylene glycol, triethylene glycol, polyethylene glycol, dipropylene glycol, polypropylene glycol, 1,4-cyclohexanedimethanol, 1,4-cyclohexanediol, bisphenol A, bisphenol F, hydrogenated bisphenol A, and hydrogenated bisphenol F.

Each of the weight average molecular weights of the thermoplastic epoxy resin, the phenoxy resin, and the saturated polyester, in terms of polystyrene by GPC (gel permeation chromatography) measurement, is independently preferably from 10,000 to 500,000, more preferably from 18,000 to 300,000, still more preferably from 20,000 to 200,000. The weight average molecular weights are each a molecular weight value in terms of standard polystyrene, calculated from an elution peak position detected by GPC. In a case in which the weight average molecular weights are each in a range of such values, the balance between thermoplasticity and heat resistance is favorable. In a case in which the weight average molecular weights are each 10,000 or more, heat resistance is excellent, and in a case in which the weight average molecular weights are each 500,000 or less, the viscosity during melting is lower and adhesiveness is higher.

Examples of the thermal conductive filler include a metal-containing particle and a non-metal particle that are each excellent in thermal conductive properties, and examples include metal, metal oxide, metal nitride, metal hydroxide, metal carbide, metal fluoride, and carbon. The thermal conductive filler may be, for example, a filler having a thermal conductivity of 10 W/(m·K) or more. The thermal conductive filler may have insulation properties or may have electroconductive properties.

The thermal conductive filler may be a particle of at least one selected from the group consisting of silver, copper, aluminum, aluminum oxide, aluminum hydroxide, magnesium oxide, beryllium oxide, boron nitride, aluminum nitride, silicon nitride, silicon carbide, silicon dioxide, aluminum fluoride, calcium fluoride, and zinc oxide. In particular, a silver particle is preferred from the viewpoint of thermal conductive properties.

Boron nitride is an insulating particle and thus is preferably used in an application in which insulation properties are demanded. However, boron nitride has a scale-like shape, thus has a thermal conductivity with anisotropy, and is easily oriented in the plane direction, thereby resulting in a tendency to allow for a lowered thermal conductivity in the thickness direction. Therefore, in a case in which boron nitride is used, it is necessary to form the adhesion layer so that boron nitride is oriented in the thickness direction from the viewpoint of thermal conductive properties, and the formation step of the adhesion layer is easily complicated.

In this regard, a particle of metal such as silver, copper, or aluminum has a high thermal conductivity and has a thermal conductivity with small anisotropy, as compared with a ceramic filler such as boron nitride. Therefore, it is not necessary to orient such a metal particle in the thickness direction during formation of the adhesion layer, the adhesion layer, which is excellent in thermal conductivity, can be easily formed, and thermal resistance of the thermal conductive sheet is suitably reduced. Furthermore, a silver particle is used as such a metal particle, whereby sintering of such particles progresses at a relatively low temperature. Therefore, a silver particle network is formed by such sintering, and a high thermal conductivity tends to be obtained as compared with other thermal conductive fillers. A sintered silver particle is excellent in close adhesiveness with an adherend such as a heat generator or a heat dissipator, and therefore thermal resistance tends to be further reduced.

The thermal conductive filler preferably includes a silver particle. In a case in which the thermal conductive filler includes a silver particle, the content of the silver particle may be from 50% by mass to 100% by mass, may be from 80% by mass to 100% by mass, or may be from 90% by mass to 100% by mass with respect to 100% by mass of the thermal conductive filler.

The thermal conductive filler includes a first thermal conductive filler having an average particle size of 500 nm or less. The first thermal conductive filler is included, whereby a thermal conductive path by sintering of the thermal conductive filler is easily formed even in a lower-temperature heating condition (for example, 180° C. or less) during adhesion of the adherend and the thermal conductive sheet, and thermal conductive properties of the thermal conductive sheet tend to be enhanced.

The average particle size of the first thermal conductive filler may be from 50 nm to 400 nm, may be from 100 nm to 300 nm, or may be from 100 nm to 200 nm.

The average particle size (D50) of the thermal conductive filler in the disclosure is measured with a laser diffraction type particle size distribution apparatus (for example, “Microtrac series MT3300” manufactured by Nikkiso Co., Ltd.) adapted to a laser diffraction-scattering method, and corresponds to a particle size at a mass accumulation of 50% in a case in which a mass cumulative particle size distribution curve is drawn from the smaller particle size side.

The thermal conductive filler may include a second thermal conductive filler having an average particle size of from 1 μm to 10 μm, together with the first thermal conductive filler having an average particle size of 500 nm or less.

Whether or not the thermal conductive filler includes the first thermal conductive filler and the second thermal conductive filler that are different in average particle size may be determined from a peak shape of a mass cumulative particle size distribution curve measured with a laser diffraction type particle size distribution apparatus adapted to a laser diffraction-scattering method.

The average particle size of the second thermal conductive filler may be from 1 μm to 5 μm, or may be from 1 μm to 3 μm.

The content of the first thermal conductive filler is preferably 15% by mass or more, more preferably 20% by mass or more, still more preferably from 25% by mass to 100% by mass, particularly preferably from 35% by mass to 90% by mass with respect to the total amount of the thermal conductive filler. The first thermal conductive filler is used in an amount of 15% by mass or more with respect to the total amount of the thermal conductive filler, whereby a thermal conductive path by sintering of the thermal conductive filler is more easily formed even in a lower-temperature heating condition (for example, 180° C. or less) during adhesion of the adherend and the thermal conductive sheet, and thermal conductive properties of the thermal conductive sheet tend to be further enhanced.

In the thermal conductive sheet of the disclosure, the adhesion layer may be located at least at one portion of a main surface of the thermal conductive layer, the adhesion layer may be located at the entire main surface, or the adhesion layer may be located at one portion (for example, a portion in contact with an adherend such as a heat generator or a heat dissipator) of the main surface.

The adhesion layer may be located at one main surface, or the adhesion layer may be located at two main surfaces.

The content of the resin component included in the adhesion layer is, for example, preferably from 1% by mass to 30% by mass, more preferably from 3% by mass to 25% by mass, still more preferably from 5% by mass to 20% by mass with respect to the total amount of the adhesion layer, from the viewpoint of the balance between thermal conductive properties and close adhesiveness.

In a case in which the adhesion layer includes a thermoplastic resin component, the content of the thermoplastic resin component may be from 50% by mass or more, may be from 60% by mass or more, may be from 80% by mass or more, or may be from 90% by mass or more with respect to the total amount of the resin component.

The upper limit of the content of the thermoplastic resin component is not particularly limited, and may be 100% by mass, or may be 95% by mass or less.

The content of the thermal conductive filler included in the adhesion layer is, for example, preferably from 70% by mass to 99% by mass, more preferably from 75% by mass to 97% by mass, still more preferably from 80% by mass to 95% by mass with respect to the total amount of the adhesion layer, from the viewpoint of the balance between thermal conductive properties and close adhesiveness.

The total content of the resin component and the thermal conductive filler included in the adhesion layer may be from 80% by mass to 100% by mass, or may be from 90% by mass to 100% by mass with respect to the total amount of the adhesion layer.

The adhesion layer optionally includes a component other than the resin component and the thermal conductive filler. Examples of such a component other than the resin component and the thermal conductive filler include the hot-melt agent (D), the antioxidant (E), and any other component, described in the section of Thermal Conductive Layer described above.

In a case in which the adhesion layer includes a thermosetting resin component, the adhesion layer is preferably in a semi-cured state from the viewpoint of increases in handling properties. For example, the adhesion layer, which is in a semi-cured state, is obtained by applying treatment of heating, drying, and/or the like to a resin composition including the thermosetting resin component and the thermal conductive filler.

In the disclosure, “semi-cured state” means that the viscosity of the adhesion layer is from 10⁴ Pa·s to 10⁶ Pa·s at an ordinary temperature (from 25 to 30° C.). The viscosity is measured with a DMA (dynamic viscoelasticity measurement apparatus; frequency 1 Hz, load 10 g: rate of temperature rise 20° C./min).

The method of obtaining the adhesion layer in a semi-cured state is not particularly limited. For example, a resin composition including the thermosetting resin component, the thermal conductive filler, a solvent, and the like may be provided to a main surface of the thermal conductive layer, and the resin composition may be heated, dried, and/or the like. Alternatively, the resin composition may be provided to a release film and then heated, dried, and/or the like, and thereafter an adhesion layer formed from the resin composition heated, dried, and/or the like may be heat roll laminated on a main surface of the thermal conductive layer. Examples of a procedure of such heating, drying, and/or the like include thermal vacuum pressing and heat roll lamination.

The average thickness of the adhesion layer is preferably from 2 μm to 50 μm, more preferably from 2 μm to 30 μm, still more preferably from 2 μm to 20 μm. In a case in which the average thickness of the adhesion layer is 2 μm or more, a gap between an adherend and the thermal conductive sheet tends to be able to be more reduced to more reduce contact thermal resistance. In a case in which the average thickness of the adhesion layer is 50 μm or less, thermal conductive properties of the thermal conductive sheet tend to be more excellent.

The arithmetic average value determined by observation of a cross section of the thermal conductive layer as a measurement subject and thus measurement of the thicknesses at random three positions with an electron microscope may be defined as the average thickness of the adhesion layer. Alternatively, the arithmetic average values in measurement of the thicknesses at random three positions with a micrometer, with respect to the thermal conductive layer not including the adhesion layer and the thermal conductive sheet including the adhesion layer, may be determined respectively as the average thickness of the thermal conductive layer and the average thickness of the thermal conductive sheet. The average thickness of the adhesion layer may be determined by subtracting the average thickness of the thermal conductive sheet from the average thickness of the thermal conductive layer.

In a case in which the adhesion layer is formed on each of two main surfaces of the thermal conductive layer, the average thickness of the adhesion layer means the total value of the thicknesses of such adhesion layers formed on such two main surfaces.

The surface roughness Ra of the thermal conductive sheet (before adhesion with the adherend) may be 10 μm or less from the viewpoint of a more reduction of a gap between the adherend and the thermal conductive sheet during adhesion with the adherend, and the surface roughness may be from 2 μm to 20 μm from the viewpoint of productivity of the thermal conductive sheet.

The surface roughness Ra in the disclosure refers to a value measured based on JIS B0601: 2013.

In the thermal conductive sheet, the thermal conductivity in the thickness direction of the thermal conductive layer is preferably higher than the thermal conductivity in the thickness direction of the adhesion layer. For example, the ratio (Thermal conductivity of thermal conductive layer/Thermal conductivity of adhesion layer) of the thermal conductivity in the thickness direction of the thermal conductive layer with respect to the thermal conductivity in the thickness direction of the adhesion layer may be more than 1, and, for example, may be from more than 1 to 20, may be from more than 1 to 10, or may be from 2 to 8.

The thermal conductivity in the thickness direction of the thermal conductive layer and the thermal conductivity of the adhesion layer can be each measured by a xenon flush (Xe-flash) method. In a case in which the resin component includes a curable resin component, the thermal conductivity of the adhesion layer means the thermal conductivity of the adhesion layer after curing.

The thermal conductivity of the adhesion layer may be 5.0 W/(m·K) or more, may be from 5.0 W/(m·K) to 20 W/(m·K), or may be from 7.0 W/(m·K) to 15 W/(m·K).

The thermal conductive sheet may have a protective film at least at one surface thereof, and preferably has a protective film on each of both surfaces thereof. Thus, a pressure-sensitive adhesive surface of the thermal conductive sheet can be protected.

Examples of the protective film include respective films of resins such as polyethylene, polyester, polypropylene, polyethylene terephthalate, polyimide, polyether imide, polyether naphthalate, and methylpentene, coat paper, a coat fabric, and foil of metal such as aluminum. The protective film may be used singly, or two or more kinds thereof may be combined and formed into a multi-layer film. The protective film is preferably surface-treated with, for example, a silicone-based or silica-based release agent.

The application of the thermal conductive sheet is not particularly limited. The thermal conductive sheet of the disclosure is particularly suitable as a film-shaped adhesion material for semiconductor chips, such as a thermal conductive sheet (TIM1; Thermal Interface Material 1) or a die-bonding film interposed between a semiconductor chip and a heat spreader in a case in which the semiconductor chip serves as a heat generator and the heat spreader serves as a heat dissipator. In a case in which the thermal conductive sheet is utilized as the die-bonding film, it may be formed as a dicing/die bonding integrated film obtained by layering with a dicing tape.

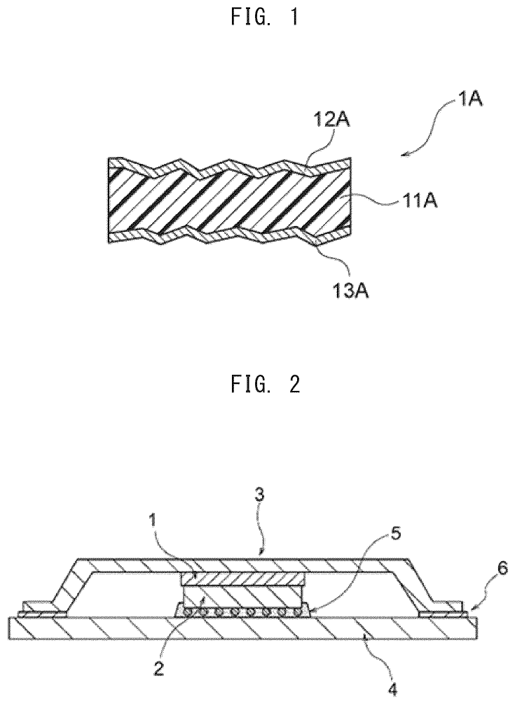

An embodiment of the thermal conductive sheet is described with reference to FIG. 1. The thermal conductive sheet of the disclosure is not limited to the following embodiments.

A thermal conductive sheet 1A illustrated in FIG. 1 includes a thermal conductive layer 11A and adhesion layers 12A and 13A, in which the adhesion layer 12A is located at one main surface of the thermal conductive layer 11A and the adhesion layer 13A is located at other main surface of the thermal conductive layer 11A.

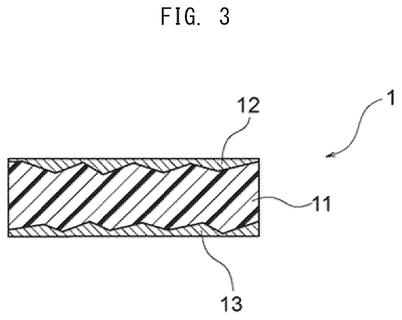

As illustrated in FIG. 1, the thermal conductive layer 11A in the thermal conductive sheet 1A may be non-flat due to asperity shapes of two main surfaces. Alternatively, the thermal conductive layer 11A in the thermal conductive sheet 1A may have two main surfaces being flat (see, for example, FIG. 3).

### [Method of Producing Thermal Conductive Sheet]

The method of producing the thermal conductive sheet is not particularly limited as long as a thermal conductive sheet having the above configuration is obtained. The method of producing the thermal conductive sheet has a step of preparing a composition containing the graphite particle (A) (also referred to as “preparation step”), a step of forming the thermal conductive layer with the composition (also referred to as “formation step”), and a step of forming the adhesion layer at least at one portion of a main surface of the thermal conductive layer (also referred to as “adhesion layer formation step”).

### <Preparation Step>

In the preparation step, a composition containing the graphite particle (A), any other components (for example, the component (B) that is liquid at 25° C., the acrylic acid ester-based polymer (C), the hot-melt agent (D), the antioxidant (E), and other components) is prepared. Any method may be used as the method of blending each component as long as it can uniformly mix each component, and is not particularly limited. A commercially available product may be obtained and prepared as the composition. The detail of preparation of the composition can be seen in paragraph of JP-A No. 2008-280496.

### <Formation Step>

In the formation step, the composition containing the graphite particle (A) and any other components is used to form the thermal conductive layer. For example, the above composition may be molded into a sheet, thereby forming the thermal conductive layer.

The formation step preferably has a step of forming the composition into a sheet to provide a sheet (also referred to as “sheet production step”), a step of producing a laminated body of the sheet (also referred to as “laminated body production step”), and a step of slicing a side edge surface of the laminated body (also referred to as “slicing step”).

### <<Sheet Production Step>>

The sheet production step may be performed by any method without any particular limitation as long as the composition obtained in the previous step can be formed into a sheet. For example, the step is preferably carried out with at least one molding method selected from the group consisting of rolling, pressing, extrusion, and coating. The detail of the sheet production step can be seen in paragraph of JP-A No. 2008-280496.

### <<Laminated Body Production Step>>

The laminated body production step is to form a laminated body of the sheet obtained in the previous step. The laminated body may be produced, for example, by sequentially overlapping a plurality of independent such sheets, by folding one such sheet, or by winding one such sheet. The detail of the laminated body production step can be seen in paragraphs to of JP-A No. 2008-280496.

### <<Slicing Step>>

The slicing step may be performed by any method without any particular limitation as long as a side edge surface of the laminated body obtained in the previous step can be sliced. Such slicing is preferably performed at a thickness of 2 times or less the mass average particle size of the graphite particle (A) from the viewpoint that an extremely efficient thermal conductive path is formed by the graphite particle (A) penetrating in the thickness direction of the thermal conductive layer, and thermal conductive properties are more enhanced. The detail of the slicing step can be seen in paragraph of JP-A No. 2008-280496.

### <Adhesion Layer Formation Step>

The adhesion layer formation step may be performed by any method without any particular limitation as long as the adhesion layer can be formed at least at one portion of a main surface of the thermal conductive layer (for example, a sliced sheet obtained by slicing). For example, a resin composition containing a thermosetting resin component, a thermal conductive filler containing a first thermal conductive filler having an average particle size of 500 nm or less, a solvent, and the like may be applied to a main surface of the thermal conductive layer, and the resin composition applied may be heated, dried, and/or the like, to volatilize the solvent. Alternatively, the resin composition may be provided to a release film and then heated, dried, and/or the like, and thereafter an adhesion layer formed from the resin composition heated, dried, and/or the like may be heat roll laminated on a main surface of the thermal conductive layer. Examples of a procedure of such heating, drying, and/or the like include thermal vacuum pressing and heat roll lamination. The adhesion layer formed on a main surface of the thermal conductive layer may be in a semi-cured state.

The method of producing the thermal conductive sheet may further have a step of attaching and laminating a protective film to the thermal conductive sheet (also referred to as “lamination step”) after the adhesion layer formation step.

### <Lamination Step>

The lamination step may be performed by any method without any particular limitation as long as the thermal conductive sheet obtained in the adhesion layer formation step can be attached to a protective film.

The thermal conductive sheet is produced by such a method, whereby an efficient thermal conductive path is easily formed and therefore a thermal conductive sheet excellent in high-thermal conductive properties and close adhesiveness tends to be obtained.

### [Heat Dissipating Device]

The heat dissipating device of the disclosure is a device including a heat generator, a heat dissipator, and the thermal conductive sheet of the disclosure, in which the thermal conductive sheet is placed between the heat generator and the heat dissipator, wherein the adhesion layer is located at least at one portion of at least one of a main surface located at the heat generator side or a main surface located at the heat dissipator side of the thermal conductive layer. In the thermal conductive layer, it is preferable that the adhesion layer is located at each of at least one portion of a main surface located at the heat generator side and at least one portion of a main surface located at the heat dissipator side, and it is more preferable that the adhesion layer is located at each of a region of a main surface located at the heat generator side, the region facing the heat generator, and a region of a main surface located at the heat dissipator side, the region facing the heat dissipator.

Examples of the heat generator include a semiconductor chip, a semiconductor package, and a power module. Examples of the heat dissipator include a heat spreader, a heatsink, and a water-cooling pipe.

Hereinafter, one example of the heat dissipating device is more specifically described with reference to FIG. 2. A heat dissipating device is described in which a semiconductor chip is used as the heat generator and a heat spreader is used as the heat dissipator. A semiconductor chip and a heat spreader are respective examples of the heat generator and the heat dissipator, and the disclosure is not limited thereto. A thermal conductive sheet 1 is used with one surface thereof closely adhering to a semiconductor chip 2 and other surface thereof closely adhering to a heat spreader 3. The semiconductor chip 2 is secured to a substrate 4 with an underfill material 5, and the heat spreader 3 is fixed to the substrate 4 with a seal material 6, thereby allowing close adhesiveness of the thermal conductive sheet 1 with the semiconductor chip 2 and the heat spreader 3 to be enhanced by pushing. It is not necessary that each one of the heat generator and the heat dissipator is provided with respect to one thermal conductive sheet 1. For example, a plurality of such semiconductor chips 2 may be provided with respect to one thermal conductive sheet 1, one semiconductor chip 2 may be provided with respect to a plurality of such thermal conductive sheets 1, or a plurality of such semiconductor chips 2 may be provided with respect to a plurality of such thermal conductive sheets 1. The adhesion layer is located at a main surface of the thermal conductive sheet 1, the surface being located at the semiconductor chip 2 side, and a main surface of the thermal conductive sheet 1, the surface being located at the heat spreader 3 side. For example, a thermal conductive sheet 1 illustrated in FIG. 3 includes an adhesion layer 13 located at a main surface of the thermal conductive sheet 1, the surface being located at the semiconductor chip 2 side, and an adhesion layer 12 located at a main surface of the thermal conductive sheet 1, the surface being located at the heat spreader 3 side. Furthermore, the adhesion layer 13 may be in contact with the semiconductor chip 2, and the adhesion layer 12 may be in contact with the heat spreader 3.

The heat dissipating device is formed by placing the thermal conductive sheet of the disclosure between the heat generator and the heat dissipator. The heat generator and the heat dissipator are layered with the thermal conductive sheet being interposed, whereby heat from the heat generator can be efficiently transferred to the heat dissipator. Such efficient heat transfer can be made to enhance the lifetime in use of the heat dissipating device, and a heat dissipating device can be provided which stably functions even in long-term use.

The temperature range in which the thermal conductive sheet can be particularly suitably used may be, for example, from −10° C. to 150° C., may be from −10° C. to 100° C., or may be from −10° C. to 80° C. Thus, examples of a suitable heat generator can include a semiconductor package, a display, LED, a light fixture, an automobile power module, and an industrial power module.

Examples of the heat dissipator include a heatsink with an aluminum or copper fin, plate, or the like, an aluminum or copper block connected to a heat pipe, an aluminum or copper block in which a cooling liquid is circulated by a pump, and a Peltier element and an aluminum or copper block provided therewith.

The heat dissipating device is configured by bringing the heat generator and the heat dissipator into contact with each surface of the thermal conductive sheet. The method of bringing the heat generator into contact with one surface of the thermal conductive sheet and the method of bringing the heat dissipator into contact with other surface of the thermal conductive sheet are not particularly limited as long as these methods are each a method in which securing can be achieved in a state of sufficient close adhesion.

Examples include a method including placing the thermal conductive sheet between the heat generator and the heat dissipator, securing the resultant with a zig capable of pressurization from about 0.05 MPa to 1 MPa, and allowing the heat generator to generate heat in this state, or to be heated to from about 80° C. to 250° C. or from about 80° C. to 200° C. with an oven or the like. Examples include a method with a pressing machine in which heating and pressurization can be made from 80° C. to 250° C. or from 80° C. to 200° C. and from 0.05 MPa to 1 MPa. A preferred pressure range is from 0.10 MPa to 1 MPa and a preferred temperature range is from 100° C. to 180° C. in this method. The pressure is set to 0.10 MPa or more or the heating temperature is set to 100° C. or more, whereby excellent close adhesiveness tends to be obtained. The pressure is set to 1 MPa or less or the heating temperature is set to 180° C. or less, whereby reliability of close adhesion tends to be more enhanced. The reason for this is considered because it is possible to inhibit the thermal conductive sheet from being excessively compressed and thus decreased in thickness, or inhibit the strain or the remaining stress of a peripheral member from being too large.

The thermal conductive sheet placed between the heat generator and the heat dissipator is not particularly limited as long as it is the above-mentioned thermal conductive sheet. For example, the thermal conductive sheet illustrated in FIG. 1 may be placed between the heat generator and the heat dissipator.

In a case in which the thermal conductive sheet 1A illustrated in FIG. 1 is used, the thermal conductive sheet 1A is heated and pressurized in a state of being placed between the heat generator and the heat dissipator, whereby the adhesion layers 12A and 13A located at a main surface of the thermal conductive sheet 1A are softened or deformed. A gap generated during heating compression bonding of the thermal conductive sheet 1A with the heat generator and the heat dissipator is embedded with the adhesion layer softened, deformed, and/or the like. Thus, not only such a gap between the thermal conductive sheet and an adherend can be reduced, but also the thermal conductive sheet and an adherend can closely adhere with the adhesion layer being interposed. Even in a case in which the thermal conductive sheet 1A having a non-flat surface, as illustrated in FIG. 1, is used, the thermal conductive sheet 1A is heated and pressurized in a state of being placed between the heat generator and the heat dissipator. Thus, the thermal conductive sheet 1A that is not flat is flattened by pressurization and thus formed into a flat thermal conductive sheet 1 as illustrated in FIG. 3 in production of the heat dissipating device, and therefore generation of a gap between the thermal conductive sheet and an adherend is suppressed.

For example, an adhesion layer including a thermosetting resin component is applied, whereby a gap between the thermal conductive sheet and an adherend is embedded with an adhesion layer deformed by heating compression bonding and the thermosetting resin component is cured by heating. Thus, the thermal conductive sheet and an adherend can be allowed to closely adhere with the adhesion layer being interposed.

For example, an adhesion layer including a thermoplastic resin component is applied, whereby a gap between the thermal conductive sheet and an adherend is embedded with an adhesion layer softened by heating compression bonding.

From the foregoing, a gap between the thermal conductive sheet and the heat generator or the heat dissipator is reduced, and contact thermal resistance is significantly reduced.

The proportion (compression ratio) of the thickness further decreased after compression bonding with respect to the initial thickness before compression bonding of the thermal conductive sheet placed between the heat generator and the heat dissipator may be from 1% to 35%.

The securing may be achieved with a zig such as a screw or a spring, in addition to a clip, and the securing is preferably achieved with a tool usually used, such as an adhesive, from the viewpoint of allowing close adhesion to be maintained.

The porosity calculated as the proportion of the area of a gas region with respect to the area of a measurement region is preferably from 0% to 25.0%, more preferably from 0% to 20.0% in at least one of the interface between the heat generator and the thermal conductive sheet or the interface between the heat dissipator and the thermal conductive sheet. Thus, a gap (for example, a gap derived from the asperity of the thermal conductive sheet and a gap derived from the asperity of the heat generator or the heat dissipator) generated during heating compression bonding of the thermal conductive sheet and the heat generator or the heat dissipator is reduced. As a result, it is presumed that contact thermal resistance is significantly reduced.

It is preferable in the disclosure that the porosity satisfies the above numerical value range in both the cases of the main surface side of the thermal conductive layer, on which the adhesion layer is located, and the main surface side of the thermal conductive layer, on which the adhesion layer is not located.

The porosity on the main surface side of the thermal conductive layer, on which the adhesion layer is located, is preferably from 0% to 10.0%, more preferably from 0% to 5.0%, still more preferably from 0% to 2.0%.

The porosity of an interface in the disclosure can be determined as follows. First, the state of attachment of the interface is observed with an ultrasonic diagnostic imaging apparatus (for example, Insight-300, Insight K.K.) in a condition of 35 MHz by a reflection method. The proportion of the area of a gas region not attached may be calculated, and the porosity of the interface may be determined based on the following expression.

Porosity of interface (%)=100×(Area of gas region/Area of measurement region)

The numerical value range of the porosity of the interface can be adjusted by adjusting, for example, the thickness of the adhesion layer, the compositional ratio of the resin composition forming the adhesion layer, and the compression ratio of the thermal conductive sheet.

### EXAMPLES

Hereinafter, the invention is described in detail with reference to Examples, but the invention is not limited to Examples.

The following materials were loaded to a kneading machine (Moriyama Co., Ltd., DS3-SGHM-E-model pressurized double-arm type kneader) so that the mixing ratio (% by volume) shown in Table 1 was achieved, and these were kneaded in a condition of a temperature of 150° C., to obtain a composition.

### <Graphite Particle (A)>

(A)-1: Scale-like expanded graphite particle (Showa Denko Materials Co., Ltd., “HGF-L”, mass average particle size: 270 μm, it was confirmed by a method with the X-ray diffraction measurement that the six-membered ring plane in a crystal was oriented in the plane direction of the scale-like particle).

### <Liquid Component (B)>

(B)-1: Isobutene-n-butene copolymer (NOF Corporation, “NOF polybutene (TM) EMAWET (registered trademark), Grade 30N”)
(B)-2: Isobutene homopolymer (NIPPON OIL CORPORATION, “Tetrax 6T”)

### <Acrylic Acid Ester-Based Polymer (C)>

(C)-1: Acrylic acid ester-copolymerized resin (butyl acrylate/ethyl acrylate/acrylonitrile/acrylic acid copolymer, weight average molecular weight: 530000, Tg=−39° C.)

### <Hot-Melt Agent (D)>

(D)-1: Hydrogenated petroleum resin (Arakawa Chemical Industries, Ltd. “ARKON P90”) <Antioxidant (E)>
(E)-1: Hindered phenol-based antioxidant (ADEKA CORPORATION “ADEKA STAB AO-60”)

### (Production of Thermal Conductive Layer)

The composition obtained by kneading was placed in an extrusion molding machine (PARKER CORPORATION, trade name: HKS40-15-type extruder), and extruded into a flat-plate shape having a width of 20 cm and a thickness of from 1.5 mm to 1.6 mm, thereby obtaining a primary sheet. The primary sheet obtained was pressed and punched with a mold blade of 40 mm×150 mm, and 61 sheets punched were layered, and pressurized in the layering direction at 90° C. for 30 minutes with a spacer having a height of 80 mm being interposed so that the height was 80 mm, thereby obtaining a laminated body of 40 mm×150 mm×80 mm. Next, a side edge surface of 80 mm×150 mm, of the laminated body, was sliced with a woodworking slicer, thereby obtaining a thermal conductive layer having a thickness of 0.11 mm.

TABLE 1

| | | % by volume |
|---|---|---|
| Graphite particle (A) | (A)-1 | 33.8 |
| Liquid component (B) | (B)-1 | 28.4 |
| | (B)-2 | 13.1 |
| Acrylic acid ester-based polymer (C) | (C)-1 | 10.0 |
| Hot-melt agent (D) | (D)-1 | 14.3 |
| Antioxidant (E) | (E)-1 | 0.4 |

| | |
|---|---|
| Total (% by volume) | 100 |

### Production of Thermal Conductive Sheet

### Comparative Examples 1 and 2

A resin composition including 12 parts by mass of a phenoxy resin, 5 parts by mass of a saturated polyester as a polymerized product of adipic acid and 1,2-propanediol, 83 parts by mass of a thermal conductive filler (silver particle, average particle size 1.5 μm), and 32 parts by mass of a solvent (cyclohexane) was prepared. The resin composition prepared was applied onto a release film, and heated in conditions of 130° C. and 5 minutes, thereby drying the solvent. Two main surfaces of the thermal conductive layer obtained as described above were heat roll laminated in a condition of 80° C., thereby obtaining a thermal conductive sheet in which an adhesion layer was formed on each of the two main surfaces.

The thickness of each of the adhesion layers before heat roll lamination, as measured with the micrometer, was 10 μm.

Samples of Comparative Examples 1 and 2 were the same samples except that pressure oven conditions (time, temperature) in production of a three-layer structure sample for thermal resistance measurement, described later, were as shown in Table 3.

### (Measurement of Thermal Resistance)

The thermal resistance was measured with a desktop type xenon flush analyzer (LFA 467 Hyper Flash). A thermal conductive sheet punched to a 15-mm square was sandwiched between 1-mm copper plates, thereby producing a three-layer structure sample. Sample production conditions included pressurization at a temperature of 150° C. and a pressure of 0.44 MPa for 3 minutes and then sufficient cooling at ordinary temperature. In order to allow a resin to sufficiently closely adhere to the copper plates and sinter the silver particle of the adhesion layer, heating was performed in a pressure oven (0.69 MPa) at a temperature for a time as shown in Table 2 or Table 3, and sufficient cooling at ordinary temperature was performed. A copper surface was subjected to blackening treatment with carbon spraying as pre-treatment of measurement, and then measurement was performed. The thermal conductivity λ, in which the influence of the copper plate content was excluded from the three-layer structure, was obtained, and the thermal resistance value X (K·cm²/W) per unit area (1 cm²) was calculated from the resultant thermal conductivity 2 and the thickness t, as follows.

$$X = ( 10 \times t ) / λ$$

t: thickness (mm) of each thermal conductive sheet of Examples 1 to 9 or Comparative Examples 1 to 6
λ: thermal conductivity (W/m·K)

### Production of Thermal Conductive Sheet

### Example 1

A resin composition including 12 parts by mass of a phenoxy resin, 5 parts by mass of a saturated polyester as a polymerized product of adipic acid and 1,2-propanediol, 83 parts by mass of a thermal conductive filler (silver particle), and 32 parts by mass of a solvent (cyclohexane) was prepared. The thermal conductive filler included in the resin composition included a silver particle (first thermal conductive filler) having an average particle size of 130 nm and a silver particle (second thermal conductive filler) having an average particle size of 1.5 μm at a mass ratio of 20:80. The resin composition prepared was applied onto a release film, and heated in conditions of 130° C. and 5 minutes, thereby drying the solvent. Two main surfaces of the thermal conductive layer obtained as described above were heat roll laminated in a condition of 80° C., thereby obtaining a thermal conductive sheet in which an adhesion layer was formed on each of the two main surfaces.

The thickness of the adhesion layer before heat roll lamination, as measured with the micrometer, was 10 μm.

### Production of Thermal Conductive Sheet

### Examples 2 to 6

Each thermal conductive sheet in which an adhesion layer was formed on each of two main surfaces was obtained in the same manner as in Example 1 except that the mass ratio of a silver particle (first thermal conductive filler) having an average particle size of 130 nm and a silver particle (second thermal conductive filler) having an average particle size of 1.5 μm in the thermal conductive filler included in the resin composition was changed as shown in Table 2.

The thickness of each of the adhesion layers before heat roll lamination, as measured with the micrometer, was 10 μm.

### Examples 7 and 8

Production of each thermal conductive sheet and measurement of thermal resistance were performed in the same manner as in Example 5 except that pressure oven conditions (time, temperature) in production of the above three-layer structure sample for thermal resistance measurement were as shown in Table 2.

### Example 9

A resin composition including 12 parts by mass of a phenoxy resin, 5 parts by mass of a saturated polyester as a polymerized product of adipic acid and 1,2-propanediol, 33 parts by mass of a silver particle (first thermal conductive filler) having an average particle size of 130 nm, 83 parts by mass of a silver particle (second thermal conductive filler) having an average particle size of 1.5 μm, and 32 parts by mass of a solvent (cyclohexane) was prepared. The resin composition prepared was applied onto a release film, and heated in conditions of 130° C. and 5 minutes, thereby drying the solvent. Two main surfaces of the thermal conductive layer obtained as described above were heat roll laminated in a condition of 80° C., thereby obtaining a thermal conductive sheet in which an adhesion layer was formed on each of the two main surfaces.

The thickness of the adhesion layer before heat roll lamination, as measured with the micrometer, was 10 μm.

TABLE 2

| | | Example | | | | | | | | |
|---|---|---|---|---|---|---|---|---|---|---|
| | Unit | 1 | 2 | 3 | 4 | 5 | 6 | 7 | 8 | 9 |
| Adhesion layer | | Both | Both | Both | Both | Both | Both | Both | Both | Both |
| | | surfaces | surfaces | surfaces | surfaces | surfaces | surfaces | surfaces | surfaces | surfaces |
| First thermal | % by mass | 20 | 30 | 40 | 50 | 80 | 100 | 80 | 80 | 29 |
| conductive filler | | | | | | | | | | |
| Second thermal | % by | 80 | 70 | 50 | 50 | 20 | 0 | 20 | 20 | 71 |
| conductive filler | equivalent | | | | | | | | | |
| Heating conditions | — | 175° C., 5 h | | | | | | 165° C., 2 h | 240° C., 2 h | 175° C., 5 h |
| Thickness after | mm | 0.111 | 0.114 | 0.112 | 0.113 | 0.110 | 0.107 | 0.107 | 0.110 | 0.118 |
| compression | | | | | | | | | | |
| Thermal resistance | K · Cm²/W | 0.084 | 9.878 | 0.974 | 0.070 | 0.065 | 0.076 | 0.076 | 0.043 | 0.073 |

TABLE 3

| | | Comparative Example | | | | | |
|---|---|---|---|---|---|---|---|
| | Unit | 1 | 2 | 4 | 4 | 5 | 6 |
| Adhesion layer | | Both surfaces | Both surfaces | Both surfaces | Both surfaces | Both surfaces | Both surfaces |
| First thermal conductive filler | % by mass | 0 | 0 | — | — | — | — |
| Second thermal conductive filler | % by mass | 100 | 100 | — | — | — | — |
| Heating conditions | — | 175° C., 5 h | 240° C., 2 h | 175° C., 5 h | 240° C., 1 h | 240° C., 2 h | 240° C., 4 h |
| Thickness after compression | mm | 0.117 | 0.109 | 0.100 | 0.095 | 0.092 | 0.092 |
| Thermal resistance | K · cm²/W | 0.089 | 0.059 | 0.117 | 0.112 | 0.112 | 0.111 |

As shown in Table 2 and Table 3, it was confirmed that the thermal resistance could be reduced in Examples 1 to 9 and Comparative Examples 1 and 2 in which the adhesion layer was formed on each of main surfaces of the thermal conductive layer, as compared with Comparative Examples 3 to 6 in which the adhesion layer was not formed on each of main surfaces of the thermal conductive layer.

It could also be confirmed that the thermal resistance was increased/decreased depending on the difference of heating conditions even in a case in which the thermal conductive layers were formed from the same compositional ratio. It could be confirmed that the thermal resistance tended to be reduced particularly by raising the heating temperature.

It could also be confirmed that the thermal resistance could be reduced in Examples 1 to 6 and 9 in which the first thermal conductive filler small in average particle size was used, as compared with Comparative Example 1 in which the thermal conductive sheet was produced in the same heating conditions. It could be further confirmed that the thermal resistance could be reduced in Example 7 even in the case of milder heating conditions than those in Comparative Example 1. It could be further confirmed that the thermal resistance could be reduced in Example 8 in which the first thermal conductive filler small in average particle size was used, as compared with Comparative Example 2 in which the thermal conductive sheet was produced in the same heating conditions. It is presumed that the reason for this is because the presence of the first thermal conductive filler small in average particle size allows a thermal conductive path to be more formed by sintering of the silver particle during heating compression bonding of the thermal conductive sheet and an adherend. It is presumed that, even in the case of heating at a lower temperature, the presence of the first thermal conductive filler small in average particle size tends to allow a thermal conductive path to be easily formed by sintering of the silver particle and allow the thermal resistance to be easily reduced.

All documents, patent applications, and technical standards described herein are herein incorporated by reference, as if each individual document, patent application, and technical standard were specifically and individually indicated to be incorporated by reference.

1. A thermal conductive sheet, comprising:
a thermal conductive layer comprising at least one graphite particle (A) selected from the group consisting of a scale-like particle, an ellipsoidal particle, and a rod-like particle, wherein, in a case of the scale-like particle, a plane direction of the scale-like particle is oriented in a thickness direction of the thermal conductive layer, in a case of the ellipsoidal particle, a longitudinal direction of the ellipsoidal particle is oriented in the thickness direction of the thermal conductive layer, and in a case of the rod-like particle, a longitudinal direction of the rod-like particle is oriented in the thickness direction of the thermal conductive layer; and
an adhesion layer that comprises a resin component and a thermal conductive filler comprising a first thermal conductive filler having an average particle size of 500 nm or less, and that is located at least at one portion of a main surface of the thermal conductive layer.

2. The thermal conductive sheet according to claim 1, wherein the resin component comprises at least one selected from the group consisting of a curable resin component, a pressure-sensitive adhesive resin component, and a thermoplastic resin component.

3. The thermal conductive sheet according to claim 2, wherein the resin component is a curable resin component and the adhesion layer is in a semi-cured state.

4. The thermal conductive sheet according to claim 1, wherein the resin component comprises a thermoplastic resin component.

5. The thermal conductive sheet according to claim 1, wherein the thermoplastic resin component comprises at least one selected from the group consisting of a thermoplastic epoxy resin, a phenoxy resin, and a saturated polyester.

6. The thermal conductive sheet according to claim 1, wherein the thermoplastic resin component comprises a phenoxy resin and a saturated polyester.

7. The thermal conductive sheet according to claim 6, wherein a content of the phenoxy resin is from 50% by mass to 90% by mass with respect to a total amount of the thermoplastic resin component and a content of the saturated polyester is from 10% by mass to 50% by mass with respect to the total amount of the thermoplastic resin component.

8. The thermal conductive sheet according to claim 1, wherein the thermal conductive filler is a particle of at least one selected from the group consisting of silver, copper, aluminum, aluminum oxide, aluminum hydroxide, magnesium oxide, beryllium oxide, boron nitride, aluminum nitride, silicon nitride, silicon carbide, silicon dioxide, aluminum fluoride, calcium fluoride, and zinc oxide.

9. The thermal conductive sheet according to claim 8, wherein the thermal conductive filler is a silver particle.

10. The thermal conductive sheet according to claim 1, wherein a content of the thermal conductive filler is from 70% by mass to 99% by mass with respect to a total amount of the adhesion layer.

11. The thermal conductive sheet according to claim 1, wherein an average thickness of the adhesion layer is from 2 μm to 50 μm.

12. The thermal conductive sheet according to claim 1, wherein the thermal conductive filler further comprises a second thermal conductive filler having an average particle size of from 1 μm to 10 μm.

13. The thermal conductive sheet according to claim 12, wherein the first thermal conductive filler and the second thermal conductive filler are silver particles.

14. The thermal conductive sheet according to claim 1, wherein a content of the first thermal conductive filler is 20% by mass or more with respect to a total amount of the thermal conductive filler.

15. A heat dissipating device, comprising a heat generator, a heat dissipator, and the thermal conductive sheet according to claim 1, wherein the thermal conductive sheet is placed between the heat generator and the heat dissipator,
wherein the adhesion layer is located at least at one portion of at least one of a main surface located at a heat generator side or a main surface located at a heat dissipator side of the thermal conductive layer.

16. A heat dissipating device comprising a heat generator, a heat dissipator, and the thermal conductive sheet according to claim 1, wherein the thermal conductive sheet is placed between the heat generator and the heat dissipator,
wherein a porosity calculated as a proportion of an area of a gas region with respect to an area of a measurement region is from 0% to 25% in at least one of an interface between the heat generator and the thermal conductive sheet or an interface between the heat dissipator and the thermal conductive sheet.

17. A method of producing the thermal conductive sheet according to claim 1, wherein the method comprises:
preparing a composition comprising the graphite particle (A),
forming the thermal conductive layer with the composition, and forming the adhesion layer at least at one portion of the main surface of the thermal conductive layer.
